(19) United States
(12) Patent Application Publication
(10) Pub. No.: US 2012/0119241 A1
(43) Pub. Date: May 17, 2012

(54) Etendue and Light Extraction System and Method

(75) Inventors: Paul Joseph Panaccione, Newburyport, MA (US); Yves Bertic, Medford, MA (US); Rommanie Kuch, N. Chelmsford, MA (US); Lidia H. Lee, Acton, MA (US); Alexei Andrew Erchak, Cambridge, MA (US)

(73) Assignee: Luminus Devices, Inc., Billerica, MA (US)

(21) Appl. No.: 12/948,727

(22) Filed: Nov. 17, 2010

(51) Int. Cl. H01L 33/58

(52) U.S. Cl. 257/98; 438/29; 257/E33.067

(57) ABSTRACT

A system and method for displacing the etendue value of light emitted as measured in a plane at an emission surface of a light emitting device to a second plane at determined height above the emission surface using a light coupling layer. The system and method increases light output or extraction of generated light from the light emitting device through a light coupling layer.

### BACKGROUND OF THE INVENTION

1. Field of the Invention

The invention relates generally to light-emitting devices, as well as related components, systems, and methods, and more particularly to extraction and optical properties of light-emitting diodes (LEDs).

2. Description of the Prior Art

There are a variety of semiconductor-based devices, such as LEDs, which emit light. The emitted light may be characterized in a number of ways. For example, light extraction is a measure of the amount of emitted light, and light collimation is a measure of the angular deviation of the light emitted from the emission surface. Another characterization is the Etendue value associated with an optical system, which is sometimes referenced in terms of area times solid angle. Light extraction relates to device efficiency, since any light generated by the device, which is not extracted, can contribute to decreased efficiency. Light collimation can be of importance if a system incorporating the LED operates more efficiently using collimated light. Likewise a system maintaining the etendue value of its source allows for greater efficiency and optical flexibility. In many applications, it can be desirable to improve light extraction and/or collimation and preserve the source etendue value.

### SUMMARY OF THE INVENTION

A system and method for preserving and/or displacing the original etendue value of a light emitting device, such as an LED, as measured at its emission surface. This system includes forming a light coupling layer on the emission window of the emission surface. The light coupling layer includes an input window and an output window separated by a distance, wherein the smallest linear dimension of the output window is greater than the distance separating the input and output windows. An etendue value as measured at the output window of the light coupling layer is proximately equal to the original etendue value as measured at the emission window prior to forming the light coupling layer thereon.

A system and method for increasing light extraction comprising: providing a multi-layer stack of materials including a layer of n-doped material, a layer of p-doped material, a light-generating region, and an emission surface having an emission window, wherein the n-doped material has a predetermined index of refraction; and forming a light coupling layer on the emission window, wherein the light coupling layer has an index of refraction less than that of the n-doped material, but greater than atmosphere, wherein the light coupling layer has a thickness greater than 10 wavelengths of emitted light from the multi-layer stack of materials, and wherein the light coupling layer has an output window equal in area to that of the emission window.

For purposes of clarity, not every component is labeled in every figure. Nor is every component of each embodiment of the invention shown where an illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF THE DRAWINGS

FIGS. 1a-b illustrates multiple views of an LED's multi-layer stack of materials and emission window.

FIG. 2a illustrates a perspective view of an LED having a light coupling layer formed thereon.

FIG. 3a illustrates a side view of an LED having a light coupling layer formed thereon and conductive wires attached thereto.

FIG. 3b illustrates an external optical element incorporated into the system shown in FIG. 3a.

FIG. 4a illustrates an LED having a light coupling layer and an optical element formed thereon.

FIG. 4b illustrates the refractive index of each layer shown in FIG. 4a.

FIG. 5 illustrates a partially encapsulated light coupling layer.

FIGS. 6a-b illustrate a side-view section of a chip-scale package incorporating an LED with and without a light coupling layer.

### DETAILED DESCRIPTION OF THE PREFERRED EMBODIMENT

Light-emitting devices (e.g., LEDs) and methods associated with such devices are provided. The devices may include a light coupling layer and an optical element that may be formed on one or more interfaces of the device (e.g., the emission surface). In some embodiments, additional layers may be present. In addition, the devices may include patterns formed on one or more interfaces of the device, light coupling layer, extraction or additional layers and may be positioned such that light generated by the device passes through the patterns when being emitted. As described further below, the patterns can be defined by a series of features (e.g., vias, posts) having certain characteristics (e.g., feature size, depth, nearest neighbor distances) which may be controlled to influence properties of the light emitted from the device including improving extraction, maintaining etendue values and/or collimation of the emitted light.

### Light Extraction and Collimation

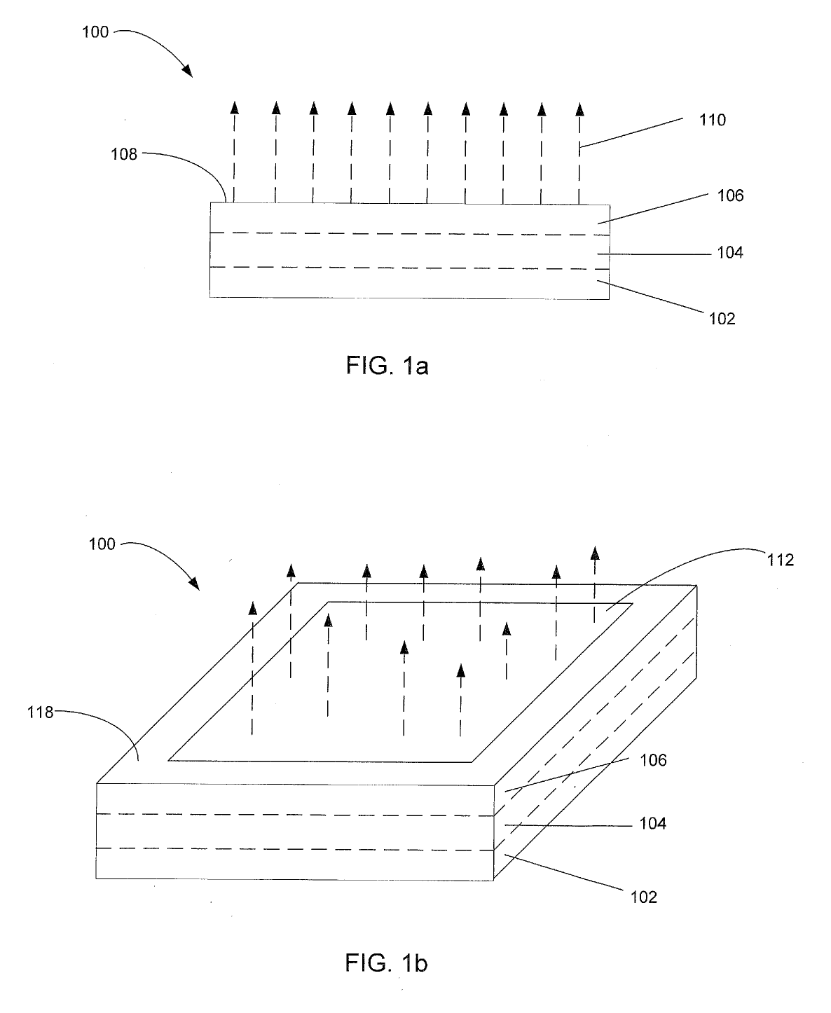

FIGS. 1a-b illustrate an LED 100 including a light-generating region 104 (e.g., the active region of the LED) and an emission surface 108 from which light 110 is emitted. The emission surface may include an emission window 112 and a non-emission portion 118. In some embodiments the emission window 112 may comprise the entire emission surface 108.

The emission region or n-doped region may be patterned with a first pattern (not shown) and a second pattern (not shown). The first pattern may be formed of a series of vias having substantially sloped sidewalls (e.g., v-shaped), while the second pattern may be formed of a series of vias having substantially vertical sidewalls. Vias of the second pattern may have a cross-sectional dimension (w2) and a depth (d2) which are less than the cross-sectional dimension (w1) and depth (d1) of the vias of the first pattern. As described further below, the presence of both patterns can enhance light extraction and/or collimation of the emitted light.

When a structure (e.g., layer, region) is referred to as being “on”, “over” or “overlying” another structure, it can be directly on the structure, or an intervening structure (e.g., layer, region) also may be present. A structure that is “directly on” or “in contact with” another structure means that no intervening structure is present. It should also be understood that when a structure is referred to as being “on”, “over”, “overlying”, or “in contact with” another structure, it may cover the entire structure or a portion of the structure.

In general, as used herein, a pattern includes two or more features having similar characteristics (i.e., shape, size). Features are portions that deviate from a reference (e.g., planar) interface. The features may be vias that extend (e.g., downwards) from the reference interface, or the features may be posts that extend (e.g., upwards) from the reference interface. It should be understood that a “via” generally refers to any type of localized void that extends from a reference interface into a material layer, including voids that extend through the entire device or voids that extend through only a portion of the device. It should also be understood that a “post” generally refers to any type of localized material region that extends from a reference interface. Suitable posts may be formed of a material or structure deposited, or otherwise formed, on the reference interface. For example, the posts may be formed of a plurality of small particles that are deposited on the reference interface using colloidal deposition techniques. Also, the posts may be nanostructures (e.g., carbon nanotubes) formed on the reference interface. Alternatively or additionally, posts may be formed by over-etching a plurality of vias in the reference interface so that some etched portions join, thereby forming posts in unetched portions of the reference interface.

In general, the features of a pattern may have any suitable shape. For example, a pattern may comprise vias having a v-shaped cross-section, but it should be appreciated that other type of cross-sections may also be utilized including trapezoidal profiles, rectangular profiles, arc profiles, semi-circular profiles, semi-elliptical profiles, and/or any other shape, as the invention is not limited in this regard. It should also be appreciated that the cross-sectional profile of the features may be different along different directions (i.e., different cross-sectional views of the feature). In some embodiments, a v-shaped cross-section may be preferred because the angled sidewalls can further enhance light extraction.

Patterns may be characterized as having an average feature size. As used herein, “average feature size” refers to the average cross-sectional dimension of features of a pattern. The average feature size of a pattern is the average of the cross-sectional dimensions of vias. The average cross-sectional dimension (i.e., feature size) may be determined by standard techniques including microscopy techniques (e.g., SEM, AFM).

In some embodiments, it may be preferable for the average feature size of one of the patterns to be greater than the average feature size of the other pattern. For example, a second pattern may have an average feature size less than about 5 times, or less than about 2 times, the peak wavelength of the emitted light. A first pattern may have an average feature size greater than about 5 times, or greater than about 10 times, the peak wavelength of the emitted light. The peak wavelength of the emitted light may depend, in part, on the specific embodiment of the device. In some embodiments, for example in which light emitted from the device is green, the second pattern has an average feature size of less than 2500 nm, or less than 1000 nm. The first pattern may have an average feature size of greater than 2500 nm, or greater than 5000 nm. In some embodiments, both the first and second patterns can have an average feature size that is greater than about 0.5 times the peak wavelength of the emitted light, or greater than about 250 nm for green emitted light.

It may be possible to enhance light extraction and/or collimation using two patterns having different average feature sizes, as noted above. For example, the pattern having the larger average feature size (i.e., larger pattern) may significantly contribute to enhancing light extraction; while, the pattern having the smaller average feature size (i.e., smaller pattern) may significantly contribute to enhancing light collimation. In some embodiments, the larger pattern may not significantly influence light collimation, and, in some embodiments, the smaller pattern may not significantly influence light extraction. However, it should also be appreciated that the smaller pattern can also influence light extraction, in conjunction with the larger pattern, so as to further enhance light extraction as compared to a situation when the smaller pattern was absent.

It should be understood that the invention is not limited to the average feature sizes noted above and that, in certain embodiments, the average feature size of the first pattern may be similar to the average feature size of the second pattern (e.g., when the first pattern and the second pattern are formed on different surfaces). In some embodiments, both of the patterns have an average feature size less than about 5 times, or less than about 2 times, the peak wavelength of the emitted light. In some embodiments, both of the patterns have an average feature size greater than about 5 times, or greater than about 10 times, the peak wavelength of the emitted light.

Patterns may also be characterized as having an average feature depth (for vias) or average feature height (for posts). As used herein, the “average feature depth” refers to the average distance vias of the pattern extend from the reference interface; while the “average feature height” refers to the average distance posts of the pattern extend from the reference interface. The “average feature depth of pattern” is the average of the depths of vias. The “average via depth” (i.e., feature depth) may be determined by standard techniques including microscopy techniques (e.g., SEM, AFM).

In some embodiments, the smaller pattern may have an average feature depth (or height) smaller than the average feature depth of the larger pattern; though, in other embodiments, the smaller pattern may have an average feature depth (or height) greater than the average feature depth of the larger pattern.

Typical average feature depths (or heights) can be between about 0.1 micron and 10 microns, though the invention is not limited in this regard. For example, the small pattern may have an average feature depth of less than about 1 micron (e.g., about 0.5 microns); while, the large pattern can have an average feature depth of between about 0.5 to 5 microns (e.g., about 2 microns). In some embodiments, it may be advantageous for the feature depth of at least one of the patterns (and, in some cases, both) to be selected so that the resulting pattern is positioned close to the light-generating region. That is, the distance between at least one of the patterns and the light-generating region is relatively small in these embodiments. For example, the distance between the upper surface of the light-generating region and the bottom surface of the pattern may be less than about 2 microns (e.g., about 0.9 microns). Positioning at least one of the patterns (e.g., such as the larger pattern) near the light-generating region may enhance light extraction in certain embodiments.

Other than feature size and depth, patterns may be characterized by the spatial periodicity (e.g., in one, two, or three dimensions) or lack thereof. In particular, patterns can be periodic (e.g., having a simple repeat cell, or having a complex repeat super-cell), periodic with de-tuning, or non-periodic. Examples of complex periodic patterns include honeycomb patterns and Archimedean patterns. Examples of non-periodic patterns include quasi-crystal patterns, for example, quasi-crystal patterns having 8-fold symmetry. A non-periodic pattern can also include random surface roughness patterns or roughening patterns. Some roughness patterns have a root-mean-square (rms) roughness about equal to an average feature size, which may be related to the wavelength of the emitted light, as previously described. In certain embodiments, the emitting surface is patterned with vias which can form a photonic lattice. Suitable LEDs having a photonic lattice patterned emission surface have been described in, for example, U.S. Pat. No. 6,831,302, entitled “Light Emitting Devices with Improved Extraction Efficiency,” filed on Nov. 26, 2003, which is herein incorporated by reference in its entirety.

In some embodiments, at least one pattern has a periodicity (or nearest neighbor feature distance) greater than about 20 times the peak wavelength of emitted light (e.g., about 45 times the peak wavelength (e.g., 25 microns)). In some embodiments, at least one pattern has a periodicity less than about 5 times the peak wavelength of emitted light.

In some embodiments, at least one pattern has a periodicity on the order of about 2 times the average feature size. As used herein, the above-mentioned periodicity refers to the length of the unit cell along at least one dimension in a periodic pattern, but in cases 10 where a pattern is not periodic, average nearest neighbor distance can be similarly used to characterize a pattern.

In the embodiment illustrated in FIG. 1b, the patterns are located at the emission window 112 of the LED and are patterned into the n-doped layer(s) 106, but it should be understood that the pattern(s) may be present at any other interface within the LED, including interfaces between two layers within the device. For example, an interface may be formed between two layers; or, between one layer and the surroundings (e.g., atmosphere or another structure mounted on the aforementioned layer). In some embodiments, one or more patterns can be located at a buried interface (e.g., at an interface between two layers) within the LED stack, or one or more patterns can be present on any other layer disposed over the n-doped layer(s).

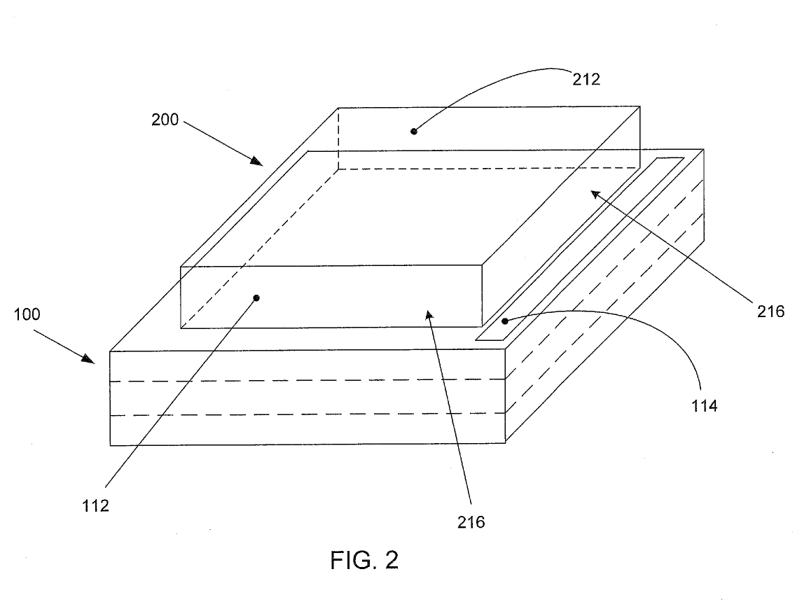

As shown in FIG. 2 a light coupling layer 200 may be formed on the emission window 112 of LED 100. Light coupling layer 200 may include an input region (not labeled), an output window 212 and a side wall(s) 216 defined by the input and output window. As described further below, a first pattern may be formed on the emission window 112 and a second pattern may be formed on a different surface, such as the input region of light coupling layer 200.

In some embodiments, one (or more) patterns cover the entire area of an interface. In other embodiments, one (or more) of the patterns cover only a portion of an interface. In embodiments in which the pattern(s) cover only a portion of the interface, it may be preferable that at least a portion of the emitted light passes through both patterns.

The above-noted pattern characteristics can be selected to produce emitted light having desired properties. Pattern characteristics that can contribute significantly to light extraction include average feature size and pattern density (e.g., which can be related to the nearest neighbor distance between features, or periodicity for periodic patterns).

A pattern with suitable feature sizes on an interface (e.g., having an average feature size less than about 5 times, or less than about 2 times, the peak wavelength of the emitted light) can create a dielectric function which varies spatially along the interface. It is believed that this dielectric function variation can alter the density of radiation modes (i.e., light modes that emerge from surface) and guided modes (i.e., light modes that are confined within a multi-layer stack) within the LED. This alteration in the density of radiation modes and guided modes within the LED can result in some light (that would otherwise be emitted into guided modes in the absence of the pattern) to be scattered (e.g., Bragg scattered) into modes that can leak into radiation modes.

The extraction of light (i.e., light occupying radiation modes), may be affected by the nearest neighbor distance between pattern features and by the feature size (i.e., filling factor within the pattern). It is believed that enhanced extraction efficiency can occur for an average nearest neighbor distance about equal to the wavelength of light in vacuum, although the invention is not limited in this respect. Enhanced extraction may be achieved since the nearest neighbor distance becomes significantly larger than the wavelength of the light which reduces the scattering effect because the dielectric function experienced by the light is more uniform. For periodic patterns containing one feature per unit cell, the nearest neighbor distance is the same as the periodicity. Feature size can also be represented by filling factor which refers to the percentage of area of material removed (or added) to form the pattern compared to the area of the interface. In some embodiments, the filling factor may be between about 25% and about 75% (e.g., about 50%).

Combining a pattern having a small feature size (e.g., having an average feature size less than about 5 times, or less than about 2 times, the peak wavelength of the emitted light) with a pattern having larger feature sizes (e.g., having an average feature size greater than about 5 times, or greater than about 10 times, the peak wavelength of the emitted light) can be beneficial in some cases. When one pattern (e.g., the large feature size pattern) is etched deeper into the material, large areas of the smaller feature pattern can be disposed closer to the active region of the device, while still allowing for suitable current spreading. Patterning close to the active region can facilitate light extraction out of the LED. In addition, sloped sidewalls for features of the pattern having larger feature sizes can further help reduce internal reflections at the interface.

In some embodiments, patterns may be tailored to produce a desired extraction of light at selected wavelength(s). For example, the selected wavelength(s) may be the peak wavelength(s) of the emitted light. In other cases, the selected wavelength(s) may be non-peak wavelengths. For example, the patterns may be tailored by controlling the average feature size and/or periodicity (for a periodic pattern) and/or average nearest neighbor distance (for a non-periodic pattern). In general, one or more of the patterns may be non-periodic, periodic with detuning, or periodic, as previously described.

The LED 100 shown in FIG. 1a includes a semiconductor stack structure comprising a light-generating region 104, p-doped layer(s) 102 disposed under the light-generating region, and n-doped layer(s) 106 disposed over the light-generating region. The LED may also include a conductive layer (not shown) that can serve as an electrical contact to the p-doped layer(s) and also as a-reflective and/or thermally conductive layer. N-metal contacts 114 as shown in the illustration of FIG. 2, are typically located on the emission surface and can have any suitable size and be located at any suitable location. Suitable contacts have been described in commonly-owned U.S. patent application Publication Ser. No. 2005-0051785 which is incorporated herein by reference and is based on U.S. patent application Ser. No. 10/871,877 entitled “Electronic Device Contact Structures,” filed on Jun. 18, 2004.

For example, the n-metal contacts could be located in between the recessed features of a pattern, to facilitate light extraction from the LED. In some cases the metal that forms the n-metal contact may be transparent to light emitted from the device. For example, the n-metal may include ITO, RuO2, and/or any other material having suitable electrical and optical properties. It should be understood that LEDs of the invention may have a variety of other structures and are not limited to the particular structure shown in FIG. 1.

The light-generating region 104 of an LED can include one or more quantum wells surrounded by barrier layers. The quantum well structure may be defined by a semiconductor material layer (e.g., for single quantum well structures), or more than one semiconductor material layers (e.g., multiple quantum well structures), having a smaller band gap as compared to the barrier layers. Suitable semiconductor material layers for the quantum well structures include InGaN, AlGaN, GaN and combinations of these layers (e.g., alternating InGaN/GaN layers with the GaN layers serving as barrier layers), although the invention is not limited to just these materials, and the quantum well(s) may be formed of any other semiconductors.

In some embodiments, the n-doped layer(s) 106 include a silicon-doped GaN layer (e.g., having a thickness of about 2000 nm thick) and/or the p-doped layer(s) 102 include a magnesium-doped GaN layer (e.g., having a thickness of about 100 nm thick). The conductive layer (not shown) may be a silver layer (e.g., having a thickness of about 100 nm) and may also serve as a reflective layer (e.g., that can reflect impinging light back towards the emission window 112) and/or a thermally conductive layer (e.g., to aid in the extraction of heat generated in the semiconductor stack). Furthermore, although not shown, other layers may also be included in the LED; for example, an AlGaN layer may be disposed between the light-generating region 104 and the p-doped layer(s) 102.

In general, the light-generating region 104, the n-doped layer(s) 106, and/or the p-doped layer(s) 102 of an LED can comprise one or more semiconductors materials, including III-V semiconductors (e.g., gallium arsenide, aluminum gallium arsenide, gallium aluminum phosphide, gallium phosphide, gallium arsenide phosphide, indium gallium arsenide, indium arsenide, indium phosphide, gallium nitride, indium gallium nitride, indium gallium aluminum phosphide, aluminum gallium nitride, as well as combinations and alloys thereof), II-VI semiconductors (e.g., zinc selenide, cadmium selenide, zinc cadmium selenide, zinc telluride, zinc telluride selenide, zinc sulfide, zinc sulfide selenide, as well as combinations and alloys thereof), and/or other semiconductors.

It should be understood that compositions other than those described herein may also be suitable for the layers of the LED.

Light may be generated by the LED 100 as follows. The conductive layer can be held at a positive potential relative to the n-doped layer(s) 106, which causes electrical current to be injected into the LED. As the electrical current passes through the LED, electrons from n-doped layer(s) 106 can combine in the active region 104 with holes from p-doped layer(s) 102, which can cause the active region to generate light. The active region can contain a multitude of point dipole radiation sources that emit light (e.g., isotropically) within the region with a spectrum of wavelengths characteristic of the material from which the active region is formed. For InGaN/GaN quantum wells, the spectrum of wavelengths of light generated by the active region can have a peak wavelength of about 445 nanometers (nm) and a full width at half maximum (FWHM) of about 30 nm, which is perceived by human eyes as blue light.

In other embodiments, the light-generating region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 nm), yellow-green (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

Upon the generation of light in the light-generating region 104, light can proceed to be emitted through the emission window 112, such that the light can pass through both the first and second pattern. In doing so, the extraction and/or collimation of light generated by the LED 100 can be influenced by the presence of the first and second patterns. Angled sidewalls of the v-groove recessed features of a pattern previously described can aid in the extraction of light generated by the LED. Furthermore, the second pattern as described above can also aid in the extraction of light. Moreover, the second pattern can also aid in the collimation of light emitted by the LED.

Light coupling layer 200 can be composed of any suitable material including a material having a suitable index of refraction (e.g., having an index greater than about 1.0, having an index greater than about 1.5, having an index greater than about 2.0, having an index substantially equal to that of the semiconductor material).

The index of refraction may be selected to maximize light extraction from the LED. For example, the index of refraction can be selected to minimize back reflection at the interface between n-doped region 106 and the light coupling layer 200. Additionally, the refractive index of light coupling layer 200 will also take into consideration the interface at the output window 212 of light coupling layer 200 and any additional material or layer that may be disposed over 212 including the surrounding atmosphere or optical element 300. In some embodiments, light coupling layer 200 is composed of one or more materials that have indices of refraction less than the index of refraction of the underlying n-doped region 106 and/or greater than the index of refraction of a material or layer that may be disposed over output window 212.

In some embodiments, light coupling layer 200 is composed of a material that is thermally stable and does not degrade during LED operation. In some embodiments, light coupling layer 200 is formed of silicone, epoxy, sol gels (e.g., spin-coated sol gels) or silicon oxides, silicon nitrides, glass, polycarbonate materials, plastics, other translucent materials or combinations thereof. Light coupling layer 200 can also include multiple layers of materials, for example, an antireflective layer may be disposed over and/or under a transparent layer.

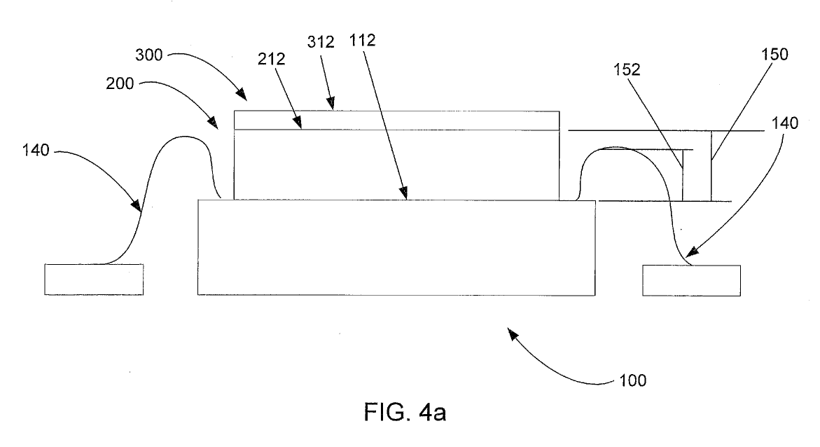

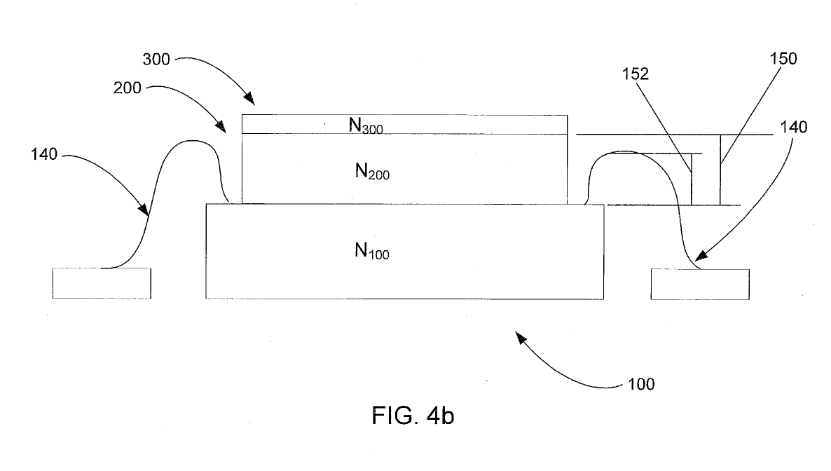

Alternatively or additionally, light coupling layer 200 may include a graded index structure where the index of refraction varies with depth. In one embodiment, the index of refraction of light coupling layer 200 can be graded from a high index value in the vicinity of the emission window 112 to an index value at the output window 212 that more closely matches the index of optical element 300 (as shown in FIGS. 4a-b) and/or the surrounding atmosphere. For example, if the n-doped layer 106 of LED 100 is exposed to an atmosphere (e.g., air) having an index of about 1.0, and the n-doped layer 106 is composed of gallium nitride having an index of about 2.3, then the index of light coupling layer 200 can be graded from about 2.3, at the interface with the emission window, to a lower index near the output window 212 (e.g., lower than 1.7, lower than 1.5). One material system that can be used to accomplish the aforementioned index grading is a graded silicon oxy-nitride layer, formed of silicon nitride at the interface with the n-doped layer and graded to silicon dioxide at the emission surface. In such a case, the silicon nitride has an index of about 2.0 and the silicon dioxide has an index of about 1.4. In some embodiments, the index grading of light coupling layer 200 may be achieved with multiple layers where the index is graded in discrete increments, so as to accomplish a similar effect as with a continuous grading.

Some embodiments provide a light coupling layer 200 made of a single silicone material have an index of refraction of about 1.41, 1.51, or 1.57. Other indices of refraction may range from 1.3 to 1.8 for light coupling layer 200. In contrast to above, some embodiments have an n-doped layer 106 with an index of refraction of about 3.5, particularly when the n-doped material is comprised of Aluminum Indium Gallium Phosphide (AlInGaP). When the light coupling layer 200 is formed on emission window 112, or the interface between the light coupling layer 200 and n-doped region 106 additional light is emitted through the system based on the principle equations provided by Snell's Law. In essence, the critical angle, or in other words, the incident angle, at which light can still refract through the interface increases to the limit of 90 degrees the closer the ratio of indices of refraction are to one. As a result of the increased incident angle, less light is subject to refraction or total internal reflection (TIR). In some embodiments the amount of light output from an LED 100 without light coupling layer 200 as compared to an LED 100 with light coupling layer 200 is greater than 5 percent, greater than 10 percent, greater than 15 percent, greater than 20 percent, and greater than 25 percent.

Additional extraction of light may be achieved by adding optical element 300 as shown in FIGS. 4a-b. Optical element 300 may be formed of silicone, epoxy, sol gels (e.g., spin-coated sol gels) or silicon oxides, silicon nitrides, fused silica, borosilicate, glass, polycarbonate materials, plastics, sapphire and other translucent materials or combinations thereof. As mentioned above having a graded index of refraction throughout the light coupling layer may help to optimize the amount of light extracted from the system. However, in some embodiments, a design having a few selected layers with discrete indexes of refraction transitioning from the index of refraction of the emission region to that of the receiving system, may achieve similar light extraction results. Furthermore, the manufacturability of such a system may be simpler to implement and cost effective.

In some embodiments optical element 300 also called a platelet has a thickness of 0.21 mm, 0.25 mm, 0.42 mm, and 0.54 mm. In one embodiment, a platelet of borosilicate glass having a thickness of 0.54 mm was used as optical element 300 and silicone gel was used as light coupling layer 200. This particular combination yielded an increase in lumen output by 16% for a red-emitting LED having a surface area of 12 mm², wherein the n-doped region contained a patterned structure thereon. In some embodiments where the LED has no patterned structure on the emission window or n-doped region even greater increases in percentage of light are achieved. For instance, increasing light output upwards of 47%.

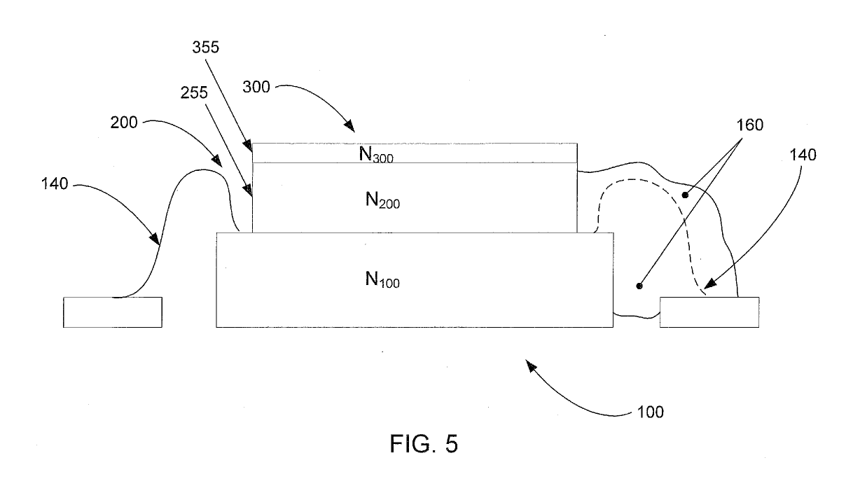

FIG. 5 shows the indices of refraction N₁₀₀, N₂₀₀, and N₃₀₀ corresponding to LED 100, light coupling layer 200, and optical element 300. In some embodiments N₁₀₀ is greater than N₂₀₀ while N₂₀₀ is greater than N₃₀₀. However, in some embodiments N200 may be less than N₃₀₀.

In some embodiments, when a first pattern and second pattern are formed at different interfaces, the first pattern may have a smaller average feature size than the second pattern (as described above), or vice-versa. In some embodiments, both patterns can have small average feature sizes (e.g., less than about 5 times, or less than about 2 times the peak wavelength of the emitted light). In some embodiments, patterns are the same pattern, located at different interfaces. The patterns may be periodic, non-periodic, or periodic with the tuning, as previously described. In some embodiments, both patterns can also be offset spatially so that features of one pattern does not directly overlie features of another pattern. In other embodiments, one pattern completely, or partially, overlies the other pattern.

In one embodiment, one pattern facilitates light extraction from the LED and the other pattern facilitates light collimation. For example, the first pattern can facilitate extraction, and the second pattern can facilitate collimation. It should also be appreciated that the patterns can also both facilitate extraction, collimation, and/or extraction and collimation.

In some embodiments, the first and second patterns may be located at the same interface, but can occupy different portions of the interface.

It should be understood that the above illustrations are but some examples of LEDs having patterns at different interfaces, and different placements of patterns are possible. For example, in another embodiment, a patchwork of patterns (located at the same interface or at different interfaces) can be used to alter the far field light pattern into a desired design.

Also, it should be understood that additional patterns may be formed at additional interfaces. For example, some embodiments may include three (or four, etc.) patterns formed at three (or four, etc.) respective interfaces within the device. In some of these embodiments, all of the patterns may be identical. In other embodiments, all of the patterns may be different. In other embodiments, some of the patterns may be different and some identical. For example, identical patterns may be formed on alternating, overlying layers. That is, the first pattern may be formed at a first interface, a second pattern formed at a second interface overlying the first interface, the first pattern formed again at a third interface overlying the second interface, and the second pattern formed again at a fourth interface overlying the third interface. Such identical or alternating patterns can be arranged vertically to form a 3-dimensional lattice on the emission surface of the LED.

Stacking multiple patterns can be beneficial for use with high index coatings or layers. By patterning various interfaces (e.g., semiconductor/light coupling layer, light coupling layer/air), the extraction of light can be increased across each of the interfaces by accounting for the index change at the interfaces. In one embodiment, various patterns can be combined, each with a different purpose (e.g., collimation patterns, extraction patterns, polarization patterns, fresnel patterns).

Patchwork patterns (e.g., at the same or different interfaces) may be beneficial since portioning off sections of the emission surface into different patterns with different attributes can allow the light to be segmented along the emission area of the LED. For example, some portions of the emitted light may collimated, some portions may be scattered diffusely, some portions may be extracted efficiently, and/or some portions may be polarized. Such a segmentation of emitted light can facilitate tuning and/or shaping of the far-field projection of the emitted light.

As noted, one or more patterns may extend into the active region of the LED structure.

In some embodiments, a larger pattern (i.e., having larger feature sizes) can extend through the active region. Such embodiments may be especially beneficial for LED structures where the active region interfaces are absorptive to light traveling within the semiconductor (e.g., an AlInGaP LED). As previously described, the sidewalls of the larger pattern may or may not contain smaller pattern features. In some embodiments, the larger pattern can extend near the reflective layer (not shown) i.e., within a distance of 0 nm, within 10 nm, within 50 nm of the reflective layer. In some embodiments, the periodicity or nearest neighbor distance of the larger pattern extending through the active region is less than about 25 microns (e.g., less than about 15 microns, less than about 5 microns).

In some embodiments, a pattern may be located at a reflective backside interface of the device, opposite the emission region. To deter absorption in certain LEDs, it may be beneficial that the backside patterning extend through the active region. In some embodiments, the emission region can include one or more patterns that can enhance light extraction and/or collimation from the device.

In some embodiments, a preferred feature sidewall slope for the emission surface pattern extending through the active region is between about 15 and about 45 degrees (e.g., about 30 degrees). In some embodiments, a preferred feature sidewall slope for the backside pattern is between about 30 and about 60 degrees (e.g., about 45 degrees). In addition, it should be appreciated that encapsulation of any LED structure with any material having a desired index (e.g., a high index material) is possible for all embodiments discussed herein.

Though the description and figures relate primarily to LEDs, it should be understood that the patterns described above can be used in connection with other light-emitting devices, such as lasers.

The light-emitting devices and structures described in the above embodiments can be fabricated using a combination of any suitable processing techniques. Such processes can include thin film deposition techniques, such as chemical vapor deposition, for depositing various materials, including semiconductors, insulators, and metals. Evaporation and sputtering can be utilized to deposit metals. Patterning processes, such as photo-lithography and nano-imprint techniques, may be used to form patterning masks. Etching processes, such as dry etching (e.g., reactive ion etching), and wet etching, may be used to pattern layers. Coating and spin-coating can be used to deposit some layers. Alternatively or additionally, injection molding can also be used to form some patterned layers. Wafer bonding processes may also be used to transfer structures and devices.

In some embodiments, patterns may be formed after the LED semiconductor stack is formed. Furthermore, other process steps, such as laser lift-off could be used to remove the growth substrate and transfer the LED semiconductor stack onto a submount, substrate, or support. In one embodiment, a reflective layer or layers are deposited on the semiconductor interface to be bonded to a submount. Once the desired surface of the LED is exposed, a plurality of patterns can be created so as to form the aforementioned embodiments and modifications thereof. It should be appreciated that the LED semiconductor stack need not necessarily be transferred to a submount, substrate, or support, and that the patterned LED structures described herein may be formed on an as-grown LED semiconductor stack without performing any stack transfer processes.

In some embodiments which can be used to form LEDs with a second pattern (e.g., a small feature size pattern) contouring a first pattern (e.g., a large feature size pattern), the process can include planarizing the top layer of the LED (e.g., the n-doped layer 106) via etching, polishing, or combination thereof, such as chemical mechanical polishing (CMP). Once the surface of the LED is planarized, the first pattern (e.g., the large feature size pattern) can be formed in the surface. For example, the first pattern (e.g., the large feature size pattern) can be formed using photolithography followed by wet and/or dry etching. For example, wet etching could be used if v-groove features are desired. After this step, the surface can be patterned so as to form the second pattern (e.g., the small feature size pattern) contouring the first pattern (e.g., the large feature size & pattern). The second pattern can be formed using imprint techniques, photolithography, e-beam lithography, x-ray lithography, and/or any other patterning process. In the case of imprint techniques, an imprintable polymer layer can be deposited on n-doped surface (e.g., via spin-coating), followed by mechanical pressing of a stamp with desired pattern, and an optional UV or heating step to cure imprint polymer. The stamp can then be removed, for example, either by pealing the stamp off or by dissolving the stamp using a suitable solution. Since imprinting techniques can use flexible stamps that allow patterning of non-planar surfaces, such as those having a first pattern, the second pattern can be imprinted in both recessed and elevated regions of the surface. Typically, this is possible when the aspect ratio (i.e., depth to size ratio) of the pre-existing surface features are not too large. Next, the pattern in the imprint polymer layer can be transferred to the underlying surface (e.g., via a wet chemical etch or a dry etch, such as reactive ion etching), and a remaining imprint polymer can be removed. Then metal n-contact electrodes (which can include a pad section for wire-bonding to the LED package) and fingers or extensions (which can spread current over the surface of the die) are formed. The formation of the electrodes includes depositing an insulating layer which can be patterned so as to be under the contact bond pads (which can prevent current from going directly into the LED under the bond pads and can direct the current to spread through the fingers). The insulating layer can be formed of an insulating material such as silicon dioxide, silicon nitride, or combinations thereof. The insulation layer can be patterned using photolithography, and then can be followed by the deposition and patterning of n-contact electrode metal. Such a process is typically accomplished with a lift-off technique, wherein a photoresist layer is deposited (e.g., spin-coated), patterned via photolithography processes, and a contact metal stack (e.g., including various layers formed of Al, Ti, Ni, Au, W, Ag, Indium-Tin-Oxide, Cu, Rh, Pt, TiN, or combinations therefore) is deposited over the patterned photoresist. The metal stack can be deposited using evaporation, sputtering, or CVD. The photoresist mask is then removed in a solvent and subsequently lifts off any overlying metal, leaving behind patterned metal layers. Optionally, the metal stack can then be heat treated. Such a fabrication process can form LEDs to those thus described herein.

In other embodiments, the first pattern (e.g., the large feature size pattern) may be formed after the formation of the second pattern (e.g., the small feature size pattern), for example, via the use of an isotropic etch and lithography steps. The first pattern (e.g., the large feature size pattern) can be formed, before or after, n-contact electrode patterning.

It should be understood that other processes may also be used to form the devices of the invention.

### Etendue Preservation

As described above, increased light extraction and collimation control are two qualities desired in certain light emitting systems. Another desired quality is the ability to maintain or preserve the initial etendue value of the light source itself. Etendue generally describes how ‘spread out’ light is at a particular point in an optical system. It may be measured from the point source or from the perspective of the receiving source. In both instances, it is a measure of an area multiplied by the solid angle (exiting or entering). Preserving the etendue value of a system allows for more flexibility and in some cases more efficient transfer of light throughput in an optical system. For example, the larger the etendue value becomes the larger the etendue value of the receiving optical element needs to be in order to capture all of the light emanating from that point. This is readily seen in automobile lights using filament-based lights as the light bulbs are surrounded by large parabolic reflectors in an attempt to capture and direct all of the emanating light.

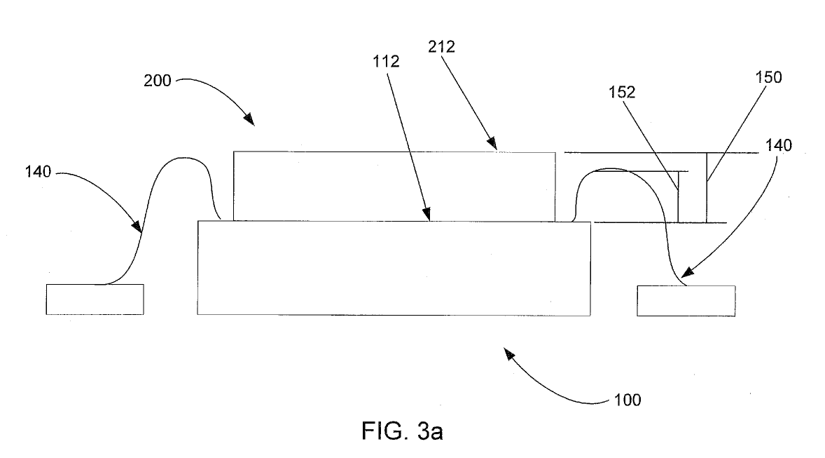

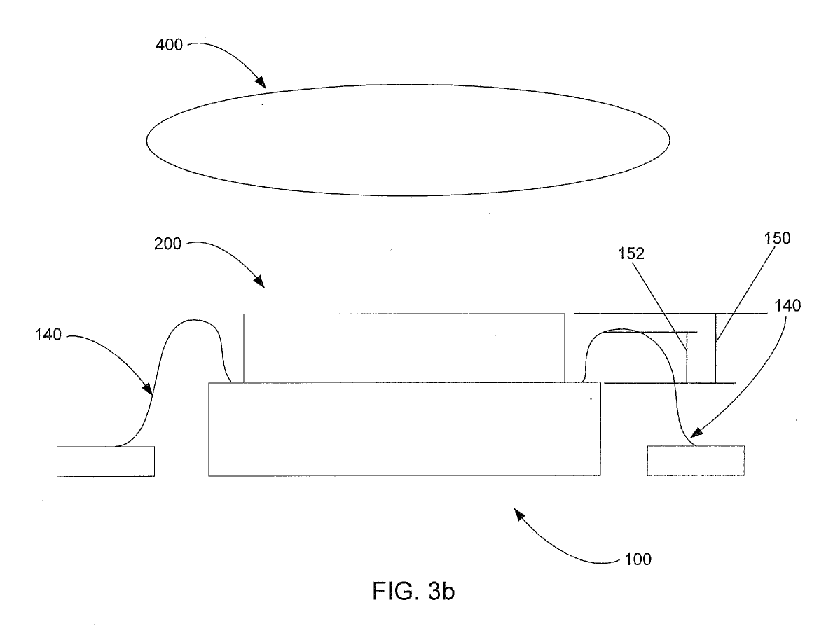

The light-emitting devices described herein preserve the original etendue value emitted by an LED and allow additional optical elements to be integrated into the system with more flexibility. FIG. 2 shows LED 100 with a light coupling layer 200 formed on the emission region 112. Additionally, FIGS. 3a and 3b illustrate conductive wires 140 attached to the emission surface 108. In some embodiments the n-metal contacts 114 reside on the non-emission portion 118 of the emission surface 108, which contains emission window 112. The non-emission portion may contain n-metal contacts for conductive wires 140, conduction ribbons, or any other type of conduction point to be attached.

The non-emission region 118 may also be used in chip-scale packaging to secure the light emitting diode 100 into a flip-chip package using an epoxy, polymer or other adhesive (conductive or non-conductive) to attach thereto. Generally, when attaching a conductive ribbon, post, lead or other conductive part to the emission surface 108, such as a conductive wire 140 in FIGS. 3a-b, the outcome results in an embodiment where the emission window 112 is no longer the highest point of the LED or multi-layer stack of materials.

For instance, conductive wires 140 displace a certain height 152 away from emission surface 108. This added height next to and above the emission window 112 sometimes creates an impediment to placing external optical elements 400 closer to emission window 112. Thus, the optical flexibility of the system is reduced. Optical flexibility is important in the manufacturability process as it allows for performance and/or cost saving measures through optical component selection.

To maintain optical flexibility in a system, light coupling layer 200 effectively displaces the etendue value of the emission window 112 by a distance 150 to the output window 212. Etendue preservation may be maintained through matching the input window area dimensions of light coupling layer 200 to the area dimensions of emission window 112 and forming light coupling layer 200 directly on emission window 112. Light originally emanating out of emission window 112, now enters the light coupling layer and exits at a distance or height 150 through the ‘new’ emission window or output surface 212. Thus, the emission window 112 is effectively displaced by a distance to the output window 212.

However, to ensure etendue preservation, output window 212 maintains substantially the same area dimensions as emission window 112 and causes light to emanate from output window 212 at substantially the same solid angle. Thus, when taking a measurement (or slicing the optical system at the emission surface plane) at the emission window the resulting etendue value will be equal or substantially equal to the measurement taken at the output window 212 plane after forming the light coupling layer 200 on the emission window 112.

Similarly, placing optical element 300 on output window 212 may cause light to be further displaced by a second distance or height. In a like manner, as described above optical element 300 may also preserve etendue preservation. This may be accomplished through matching the output window 312 of optical element 300 maintains the same area dimensions as emission window 112. Furthermore, the light passing through light coupling layer 200 and optical element 300 emanates at a solid angle at the plane of output window 312 substantially the same as at emission window 112 prior to forming the light coupling layer 200 or optical element 300 thereon.

In some embodiments, the height of 150 is equal to that of 152. In other embodiments, height 150 is greater than 152. In some instances height 150 is greater than 10 wavelengths of emitted light from LED 100 as measured in the light coupling layer, greater than 5 microns, greater than 10 microns and greater than 20 microns.

Light coupling layer 200 has a height 150 that is less than the smallest linear dimension of its output window 212. For example, if the output window was rectangular in shape and its smallest dimension was a linear edge of 1 mm in length the height of light coupler layer would be less than 1 mm in height. If the output window was circular in shape and the smallest linear dimension were the diameter the height would be less than the diameter. Most often, the height is substantially less than the smallest linear dimension. For instance in some embodiments, the height of light coupling layer is approximately 20 microns, with the smallest linear dimension being no less than 1 mm in length.

Additionally, output window 212 of light coupling layer 200 also provides an etendue value proximately equal to that of the emission region. In some embodiments, this is accomplished through matching the dimension and area of emission window 112 with that of output window 212. In some embodiments small variations of less than five percent in total area, dimension length, and/or curvature may still provide etendue values at the output window 212 of proximate values to the original entendue value at emission window 112. This may cause the displaced etendue value to vary by less than five percent, less than three percent and in some cases less than one percent from the etendue value of emission window 112.

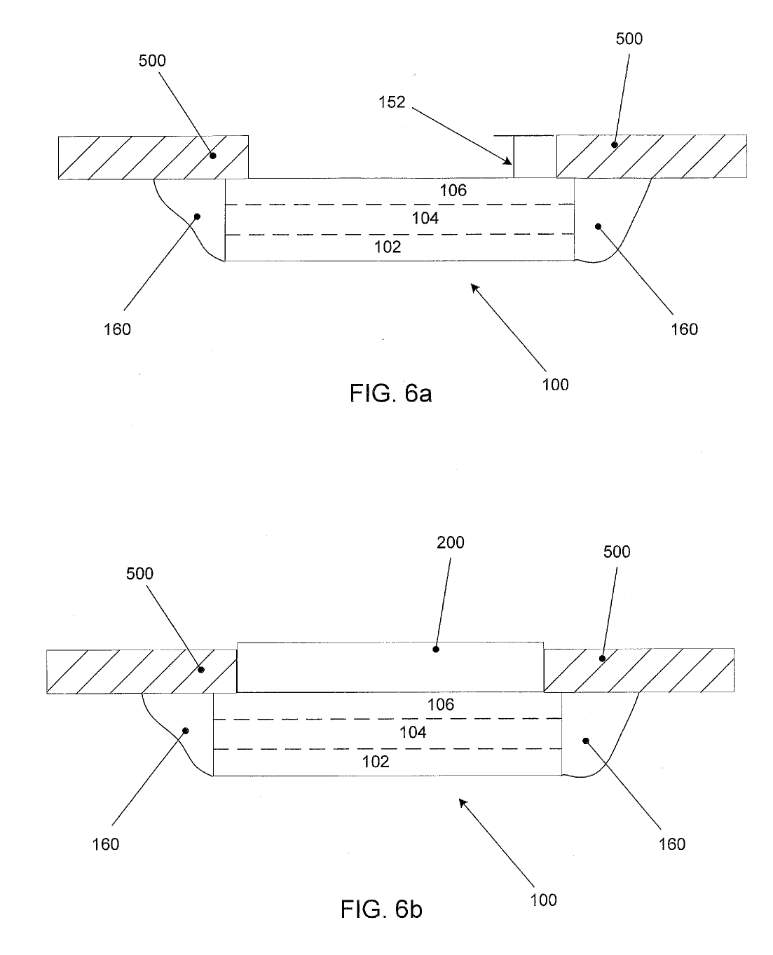

Some embodiments include coating the sidewalls 216 with a reflective material 255 (and reflective material 355 for the sidewalls of optical element 300 as shown in FIG. 5) to direct all light entering the light coupling layer to exit only through output window 212. Directing light entering light coupling layer 200 out through the output window 212 may also be accomplished by partially encapsulating light coupling layer 200 (as shown in FIG. 5). Such encapsulating or potting materials 160 (as shown in FIG. 5) may be formed of an epoxy, or polymer material that provide rigidity and protection to conductive wire bonds 140, conductive ribbons or other conductive leads, as well as become supporting structure for a chip-scale packaging design (as shown in FIGS. 6a-b). These materials are known in the microelectronics industry and include many silicone-based polymers and epoxies. They are sometimes referred to as encapsulating, potting, dam-and-fill, or even glob-top materials. These materials often provide the rigidity desired to create a robust system.

In some embodiments, the angle of incidence at which light approaches sidewall 216 (as shown in FIG. 2) may be large enough that an additional coating or encapsulant may not be necessary, as a result of the refractive and reflective properties of light coupling layer 200.

In the embodiments shown in FIGS. 6a-b, LED 100 is attached to chip-scale package 500. This may be accomplished through flip-chip processing known in the art. Chip-scale package may contain conductive leads for driving current through LED 100. Potting or encapsulating material 160 as shown helps in further securing LED 100 to chip-scale package 500 and provides increased rigidity as discussed above. FIG. 6a illustrates a height 152 that the chip scale package 500 rises above the emission surface of LED 100. It may be advantageous for reasons discussed to incorporate light coupling layer 200 onto the emission window of LED 100 to not only increase light output, but to raise the effective emission surface by a height of at least 152 or greater. Raising the effective emission surface, provides greater optical flexibility as it preserves the same etendue value from the emission window of LED 100 to the output window of light coupling layer 200.

Chip-scale package 500 may be comprised of several materials include glass, conductive leads, FR-4 material, and other materials known in the chip-scale packaging field.

As mentioned, by displacing the effective etendue value from the emission window 112 to output window 212, light coupling layer 200 allows for optical advantages. One such advantage is the placement of additional external optical elements 400 in the system. For example, additional optical elements may now be positioned so as to touch the light coupler's output window 212 without undue impediments such as conductive wires, leads, or posts in the way. Additionally, the numerical aperture of an additional optical element may be reduced when capturing all of the emission rays of light from output window 212. The closer and unimpeded placement provides for such a design. Generally, the numerical aperture of an optical element increases in size the further away it is displaced from a non-collimated light source. As previously described, collimating a light source or reducing the dispersion angle is one way to effectively control the size of optical elements used while the other is placing those optical elements in close proximity to the emission source.

The above description is merely illustrative. Having thus described several aspects of at least one embodiment of this invention including the preferred embodiments, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A light emitting device comprising:
a multi-layer stack of materials including a layer of n-doped material, a layer of p-doped material, a light-generating region, and an emission surface having an emission window; and
a light coupling layer formed on the emission window, wherein the light coupling layer includes an input window and an output window separated by a distance, wherein the smallest linear dimension of the output window is greater than the distance separating the input and output windows, and wherein an etendue value as measured at the emission window prior to forming the light coupling layer thereon is proximately equal to an etendue value as measured at the output window after forming the light coupling layer thereon.

2. The light emitting device of claim 1, wherein the output of light as measured at the output window after forming the light coupling layer thereon is greater than the output of light as measured at the emission window prior to forming the light coupling layer thereon.

3. The light emitting device of claim 2, wherein the increase in light output is greater than 10 percent.

4. The light emitting device of claim 1, wherein the distance between the input window and the output window of the light coupling layer is greater than ten wavelengths of the emitting light.

5. The light emitting device of claim 1, wherein the distance between the output window of the light coupling layer and the emission window is greater than 5 microns.

6. The light emitting device of claim 1, wherein the n-doped material has a pattern.

7. The light emitting device of claim 1, wherein the output window of the light coupling layer is patterned.

8. The light emitting device of claim 1, wherein the input window of the light coupling layer is patterned.

9. The light emitting device of claim 1, further including an optical element formed on the output window of the light coupling layer, wherein the optical element has an input and output window separated by a second distance, wherein the etendue value as measured at the emission window prior to forming the light coupling layer thereon is substantially preserved from the emission window to the output window of the optical element.

10. The light emitting device of claim 9, wherein the output of light as measured at the output window of the optical element is greater than the output of light measured at the output window of the light coupling layer prior to forming the optical element thereon.

11. The light emitting device of claim 1, wherein the light coupling layer is comprised of a silicone material.

12. The light emitting device of claim 9, wherein the optical element is comprised of a glass material.

13. The light emitting device of claim 9, wherein the optical element is comprised of a polycarbonate material.

14. The light emitting device of claim 1, wherein a portion of the light coupling layer is coated with a reflective material.

15. The light emitting device of claim 1, wherein a portion of the light coupling layer is at least partially encapsulated in a potting material.

16. The light emitting device of claim 1, wherein the emission window has an area greater than 1 mm².

17. The light emitting device of claim 1, wherein the emission window has an area equal in size to the area of the output window of the light coupling layer.

18. The light emitting device of claim 9, wherein the emission window has an area equal in size to the area of the output window of the optical element.

19. The light emitting device of claim 1, wherein the emission window has an index of refraction greater than the index of refraction of the light coupling layer.

20. The light emitting device of claim 9, wherein the light coupling layer has an index of refraction less than the index of refraction of the n-doped material and greater than the index of refraction of the optical element extraction layer.

21. The light emitting device of claim 1, wherein at least one conductive lead is attached to the emission surface, wherein the conductive lead forms a first height immediately above the emission surface, and wherein the light coupling layer formed on the emission window rises at a second height equal to or greater than the first height formed by the conductive lead.

22. A method for displacing an etendue value:
providing a light emitting device having an emission window wherein a predetermined etendue value is measurable; and
forming a light coupling layer over the emission window, wherein an effective emission surface is created at a distance above the emission window, and wherein the etendue value of the effective emission surface is proximately equal to that of the emission window.

23. A method for increasing light extraction comprising:
providing a multi-layer stack of materials including a layer of n-doped material, a layer of p-doped material, a light-generating region, and an emission surface having an emission window, wherein the n-doped material has a predetermined index of refraction; and
forming a light coupling layer on the emission window, wherein the light coupling layer has an index of refraction less than that of the n-doped material, but greater than atmosphere,
wherein the light coupling layer has a thickness greater than 10 wavelengths of emitted light from the multi-layer stack of materials, and
wherein the light coupling layer has an output window equal in area to that of the emission window.

24. The method of claim 23, further including forming an optical element on the output window of the light coupling layer, wherein the optical element has an index of refraction less than that of the light coupling layer, but greater than that of atmosphere.
